(19) United States
(12) Patent Application Publication
(10) Pub. No.: US 2013/0279119 A1
(43) Pub. Date: Oct. 24, 2013

(54) ELECTRONIC ASSEMBLIES AND METHODS OF FABRICATING ELECTRONIC ASSEMBLIES

(71) Applicants: Vicentiu GROSU, Harbor City, CA (US); Mark D. KORICH, Chino Hills, CA (US); Terence G. WARD, Redondo Beach, CA (US); Gregory S. SMITH, Woodland Hills, CA (US)

(72) Inventors: Vicentiu GROSU, Harbor City, CA (US); Mark D. KORICH, Chino Hills, CA (US); Terence G. WARD, Redondo Beach, CA (US); Gregory S. SMITH, Woodland Hills, CA (US)

(73) Assignee: GM GLOBAL TECHNOLOGY OPERATIONS LLC, DETROIT, MI (US)

(21) Appl. No.: 13/481,181

(22) Filed: May 25, 2012

Related U.S. Application Data
(60) Provisional application No. 61/636,486, filed on Apr. 20, 2012.

(51) Int. Cl. H05K 7/20; B21D 53/02

(52) U.S. Cl. 361/722; 29/890.03

(57) ABSTRACT

Electronic assemblies and methods of fabricating electronic assemblies are provided herein. The electronic assembly includes a heat sink, a metal layer, and an electrical insulator layer. The metal layer defines at least a portion of an electrical circuit. The electrical insulator layer is disposed between the heat sink and the metal layer and is directly bonded to the heat sink.

### CROSS-REFERENCE TO RELATED APPLICATIONS

This application claims the benefit of U.S. Provisional Patent Application No. 61/636,486 filed Apr. 20, 2012, the entire contents of which are herein incorporated by reference.

### TECHNICAL FIELD

The present invention generally relates to electronic assemblies and methods of fabricating electronic assemblies, and more particularly relates to electronic assemblies that include an electrical insulator layer directly bonded to a heat sink and methods of fabricating such electronic assemblies.

### BACKGROUND

Electronic assemblies are used in a wide variety of industries including the automotive industry, the consumer products industry, and the like. Bonding and joining technology is fundamental in the manufacture of these electronic assemblies. Power modules are examples of one type of electronic assembly in which forming robust bonds between the various components can be challenging. Power modules typically include electronic components that have high power losses in terms of heat, such as semiconductor dies that include power transistors, diodes, and the like. These modules may be part of a more extensive electronic system responsible for controlling speed and torque of electrical loads like motors.

Typically, power modules include a thermal stack that comprises multiple dies, e.g., semiconductor dies, bonded to a high power substrate, such as a Direct Bonded Copper (DBC) substrate, a Direct Bonded Aluminum (DBA) substrate, or an Active Metal Brazing (AMB) substrate, which is bonded to a heat sink. These high power substrates are relatively expensive and are typically configured as a tri-layer structure that includes a ceramic layer interposed between two metal layers. The assembly of the substrate with the heat sink usually employs a conventional bonding and joining technology such as soldering to form a solder joint(s) that bonds the substrate to the heat sink. Unfortunately, the solder joint(s) often rapidly degrades at the relatively high module temperatures achieved during normal operation of power modules and the differences in thermal expansion of the individual layers of the substrate, the solder joint(s), and the heat sink. Additionally, the substrate can also crack from stresses produced from these differences in thermal expansion during normal operation. As such, performance and reliability of the electronic assembly can be affected. Also, electronic assemblies that include tri-layer structures of traditional high power substrates can require additional packaging space to accommodate the thickness of the tri-layer structure. In applications where packaging space is limited, e.g., integrating an inverter into a motor, the integration of the electronic assembly may be limited and/or require complex shapes, e.g., circular inverter, resulting in cost prohibitive substrates.

Accordingly, it is desirable to provide electronic assemblies that are less costly and/or that have improved performance and reliability, and methods for fabricating such electronic assemblies. Moreover, it is desirable to provide electronic assemblies that have greater packaging flexibility and integration in applications where packaging space is limited, and methods for fabricating such electronic assemblies. Furthermore, other desirable features and characteristics of the present invention will become apparent from the subsequent detailed description and the appended claims, taken in conjunction with the accompanying drawings and the foregoing technical field and background.

### BRIEF SUMMARY

An electronic assembly is provided herein. In one embodiment, the electronic assembly comprises a heat sink, a metal layer, and an electrical insulator layer. The metal layer defines at least a portion of an electrical circuit. The electrical insulator layer is disposed between the heat sink and the metal layer and is directly bonded to the heat sink.

In another embodiment, the electronic assembly comprises a heat sink and a metal layer that defines at least a portion of an electrical circuit. An electrical insulator layer is disposed between and directly bonded to the heat sink and the metal layer. The electrical insulator layer has a dielectric strength of at least about 2 kV/mm. A die is bonded to the metal layer and is electrically coupled to the electrical circuit.

A method of fabricating an electronic assembly is provided herein. In one embodiment, the method comprises the steps of forming an electrical insulator layer that is disposed between a heat sink and a metal layer and that is directly bonded to the heat sink. At least a portion of an electrical circuit is defined in the metal layer.

### BRIEF DESCRIPTION OF THE DRAWINGS

The embodiments will hereinafter be described in conjunction with the following drawing figures, wherein like numerals denote like elements, and wherein:

FIG. 1 is a plan view of an electronic assembly at a later stage of its fabrication in accordance with an embodiment;

FIG. 2 is a cross-sectional view of an electronic assembly along line 2-2 depicted in FIG. 1 in accordance with an embodiment;

FIG. 3 is a flowchart of a method of fabricating an electronic assembly in accordance with an embodiment; and

FIG. 4 schematically illustrates, in cross-sectional view, an electronic assembly during intermediate stages of its fabrication in accordance with an embodiment.

### DETAILED DESCRIPTION

The following detailed description is merely exemplary in nature and is not intended to limit the invention or the application and uses. Furthermore, there is no intention to be bound by any theory presented in the preceding technical field, background, brief summary or the following detailed description.

Various embodiments contemplated herein relate to electronic assemblies and methods of fabricating electronic assemblies. Unlike the prior art, the embodiments described herein provide an electronic assembly that has an electrical insulator layer formed between a heat sink and a metal layer. The electrical insulator layer is directly bonded to the heat sink. In one embodiment, the electrical insulator layer is formed of a dielectric material (e.g., an enamel or polymer) that is dried, heated, and/or cured directly on the surfaces of both the heat sink and the metal layer to affix the electrical insulator layer to these surfaces without the use of solder or other bonding or joining material.

In an embodiment, the metal layer is patterned and etched, for example, to define at least a portion of an electrical circuit. A die is bonded, e.g. with solder, sintered metal, or the like, to the metal layer and is electrically coupled to the electrical circuit. The electrical insulator layer electrically isolates the heat sink from the electrical circuit formed in the metal layer. As such, the electrical insulator layer and the metal layer effectively function together as a high power substrate that is configured as a bi-layer structure. In one embodiment, this bi-layer structure is less expensive than the tri-layer structures of traditional high power substrates, such as DBC substrates, DBA substrate, and AMB substrate. Moreover, the electrical insulator layer does not require the use of solder or other bonding or joining material to bond to the heat sink and therefore, degradation of any bonding or joining material, e.g., solder joint, that would otherwise be used to bond to the heat sink is eliminated. Additionally, in one embodiment, the bi-layer structure has fewer layers with different thermal expansions than tri-layer structures of traditional high power substrates and therefore, less stress is produced during normal operation of the electronic assembly, thereby reducing, minimizing, or eliminating cracking between the layers. Also, because the bi-layer structure has fewer layers than tri-layer structures of traditional high power substrates, the overall thickness of the electronic assembly can be reduced allowing for greater packaging flexibility and integration in applications where packaging space is limited.

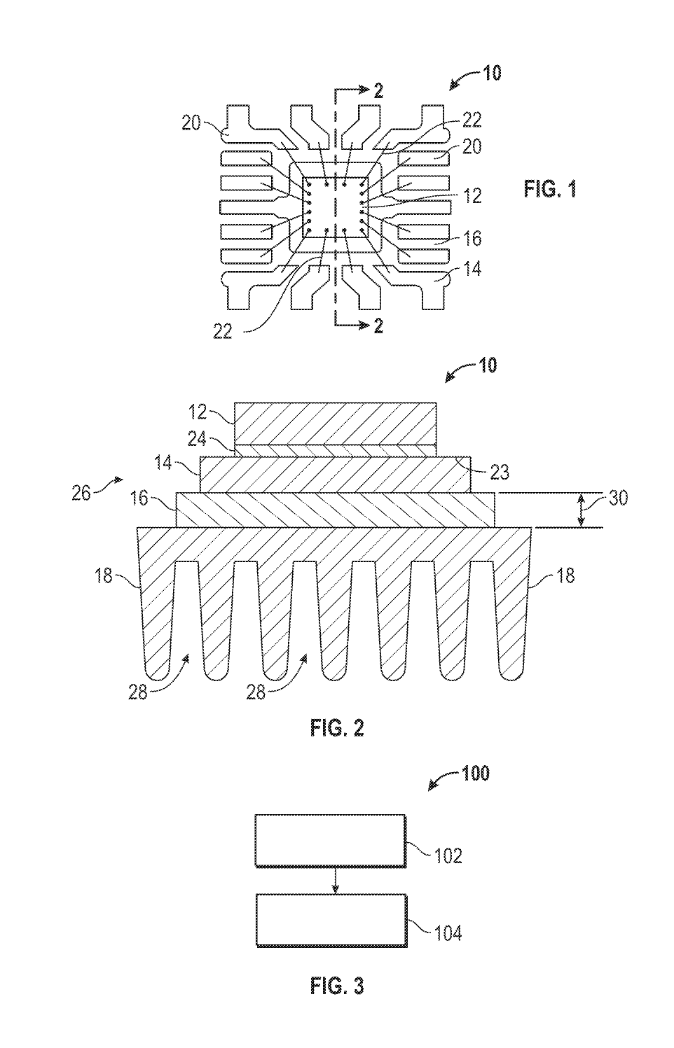

FIG. 1 is a plan view of an electronic assembly 10 in accordance with an embodiment. FIG. 2 is a cross-sectional view of an electronic assembly 10 along line 2-2 depicted in FIG. 1. As illustrated, the electronic assembly 10 is shown at a later fabrication stage. Various steps in the manufacture of electronic assemblies are well known and so, in the interest of brevity, many conventional steps will only be mentioned briefly herein or will be omitted entirely without providing the well known process details. The electronic assembly 10 comprises a die 12, a metal layer 14, an electrical insulator layer 16, and a heat sink 18. Notably, the illustrated portion of the electronic assembly 10 includes only a single die 12, although those skilled in the art will recognize that an actual electronic assembly could include a plurality of dies.

The die 12 may be, for example, a semiconductor die that includes power transistors, diodes, and/or the like, or any other electronic device. The metal layer 14 defines at least a portion of an electrical circuit 20. As shown, the die 12 is electrically coupled to the electrical circuit 20 via a plurality of wire bonds 22 and is bonded to a surface 23 of the metal layer 14 via a bond joint 24. The bond joint 24 may be formed of solder to define a solder joint or alternatively, may be formed from sintered metal or other bonding or joining material known to those skilled in the art.

In an embodiment and as will be discussed in further detail below, the electrical insulator layer 16 is directly bonded to the heat sink 18. As illustrated, the electrical insulator layer 16 is also directly bonded to the metal layer 14. As such, the electronic assembly 10 forms a thermal stack 26 for transferring heat from the die 12 to the heat sink 18. The heat sink 18 includes multiple channels 28 through which coolant (e.g., air, water, a water and ethylene glycol mixture, and the like) can flow, for example, via natural convection or forced convection. In particular, when the electronic assembly 10 is operating, the flow of coolant through the channels 28 reduces the temperature of the heat sink 18 and, in turn, reduces the temperatures of the electrical insulator layer 16, the metal layer 14, and the die 12.

The electrical insulator layer 16 comprises a dielectric material and electrically isolates the heat sink 18 from the electrical circuit 20 formed in the metal layer 14. The thickness (indicated by double headed arrow 30) and dielectric properties of the electrical insulator layer 16 are adapted so that the electrical insulator layer 16 has a relatively high dielectric strength for electrical isolation. In an embodiment, the electrical insulator layer 16 has a dielectric strength of about 2 kV/mm or greater, such as about 8 kV/mm or greater, for example from about 8 to about 100 kV/mm. In one embodiment, the thickness 30 of the electrical insulator layer 16 is from about 0.1 to about 0.7 mm.

In one embodiment, the dielectric material of the electrical insulator layer 16 comprises an enamel and/or a polymer(s). For example, the dielectric material of the electrical insulator layer 16 may be an enamel that comprises silicon oxide and metal oxide(s). Alternatively, the dielectric material of the electrical insulator layer 16 may be a polymer or polymers, such as polydimethylsiloxane, epoxy, polyester, polyvinyl ester, and/or a bismaleimide-based polymer, for example polydimethylsiloxane.

In an embodiment, the electrical insulator layer 16 has a relatively high thermal conductivity. In one example, the electrical insulator layer 16 has a thermal conductivity of about 0.3 W/m° K or greater, such as from about 0.3 to about 1000 W/m° K or greater. A filler having a relatively high electrical resistivity, such as from about 10² to about 10¹⁴ (ohms cm) or greater, and a relatively high thermal conductivity, such as from about 30 to about 300 W/m° K or greater, may be dispersed in or otherwise incorporated into the dielectric material to increase the thermal conductivity of the electrical insulator layer 16 while maintaining dielectric properties suitable for electrical isolation. In one embodiment, the filler comprises aluminum oxide, boron nitride, magnesium oxide, silicon carbide, silicon, aluminum nitride, and/or beryllium oxide.

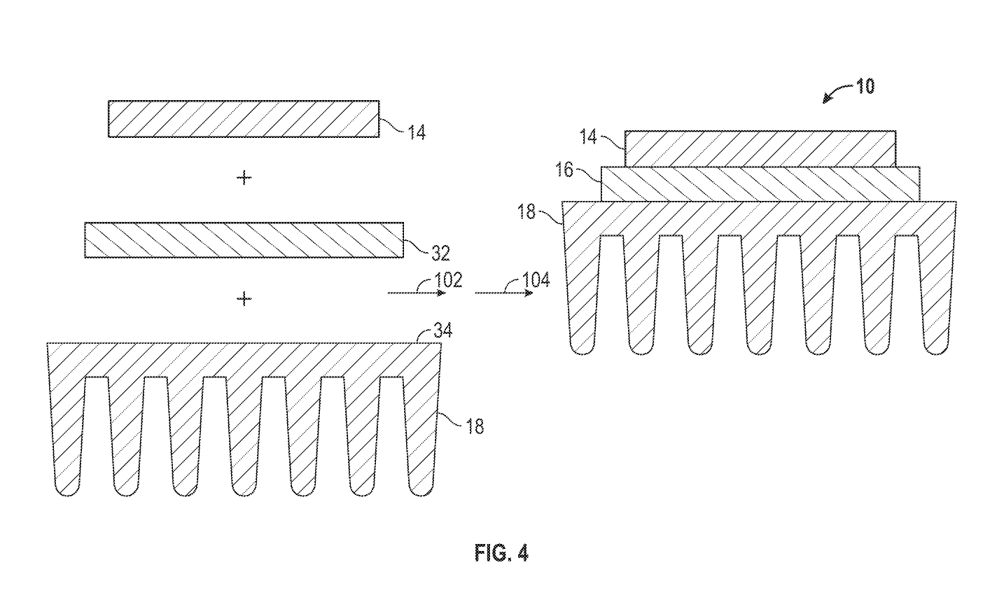

Referring to FIGS. 3 and 4, a flowchart of a method 100 of fabricating the electronic assembly 10 and a schematic illustration, in cross-sectional view, of the electronic assembly 10 during intermediate stages of its fabrication in accordance with various embodiments are provided, respectively. As illustrated, the electronic assembly 10 is fabricated by forming (step 102) the electrical insulator layer 16 positioned between the heat sink 18 and the metal layer 14. The electrical insulator layer 16 is directly bonded to the heat sink 18. In one embodiment, the electrical insulator layer 16 is formed by applying an electrical insulator forming material 32 onto the heat sink 18. The electrical insulator forming material 32 may be an enamel coating or an uncured polymeric material, such as an uncured adhesive sheet or polymeric coating. The electrical insulator forming material 32 may be deposited or positioned onto the surface 34 of the heat sink 18 using a liquid dispensing process, a spray process, or a laminating process. The metal layer 14 is positioned along the electrical insulator forming material 32 either prior to, during, or subsequent to depositing or positioning the electrical insulator forming material 32 on the heat sink 18. The electrical insulator forming material 32 is then dried, heated, and/or cured to form the electrical insulator layer 16. In one example, the electrical insulator forming material 32 is an enamel coating that is deposited onto the heat sink 18 using a liquid dispensing process or a spray process, and then is dried and/or heated to form the electrical insulator layer 16. In another example, the electrical insulator forming material 32 is a polymer coating that is deposited onto the heat sink 18 using a liquid dispensing process or a spray process, and then is heated and/or cured to form the electrical insulator layer 16. In yet another example, the electrical insulator forming material 32 is an uncured adhesive sheet that is positioned on the heat sink 18 using a lamination process, and then is heated and/or cured to form the electrical insulator layer 16.

In one embodiment, at least a portion of an electrical circuit 20 (see FIG. 1) is defined (step 104) in the metal layer 14. Although defining (step 104) the electrical circuit 20 in the metal layer 14 is illustrated as occurring subsequent to forming (step 102) the electrical insulator layer 16, the electrical circuit 20 may alternatively be defined (step 104) in the metal layer 14 either prior to or during forming (step 102) of the electrical insulator layer 16. In one embodiment, the electrical circuit 20 is formed (step 104) in the metal layer 14 using well known lithography and etching techniques or alternatively, using other circuit forming techniques known to those skilled in the art.

The process continues as discussed above in relation to FIGS. 1 and 2 by forming the bond joint 24, e.g. solder joint, sintered metal, or the like, between the die 12 and the metal layer 14 using well known bonding and joining techniques. The die 12 is electrically coupled to the electrical circuit 20 via the plurality of wire bonds 22 or other interconnects known to those skilled in the art to form the electronic assembly 10 as illustrated in FIGS. 1 and 2.

Accordingly, electronic assemblies and methods of fabricating electronic assemblies have been described. Unlike the prior art, the embodiments described herein provide an electronic assembly that has an electrical insulator layer formed between a heat sink and a metal layer. In one embodiment, the electrical insulator layer is directly bonded to the heat sink and the metal layer without the use of solder or other bonding or joining material. The metal layer defines at least a portion of an electrical circuit. A die is bonded, e.g. with solder, sintered metal, or the like, to the metal layer and is electrically coupled to the electrical circuit. The electrical insulator layer electrically isolates the heat sink from the electrical circuit formed in the metal layer. As such, the electrical insulator layer and the metal layer can effectively function together as a cost effective bi-layer substrate structure. Moreover, the electrical insulator layer does not require the use of solder or other bonding or joining material to bond to the heat sink and therefore, degradation of any bonding or joining material, e.g., solder joint(s), that would otherwise be used to bond to the heat sink(s) is eliminated. Additionally, in one embodiment, the bi-layer structure has fewer layers with different thermal expansions than tri-layer structures of traditional high power substrates and therefore, less stress is produced during normal operation of the electronic assembly, thereby reducing, minimizing, or eliminating cracking between the layers. Also, because the bi-layer structure has fewer layers than tri-layer structures of traditional high power substrates, the overall thickness of the electronic assembly can be reduced allowing for greater packaging flexibility and integration in applications where packaging space is limited.

While at least one embodiment has been presented in the foregoing detailed description, it should be appreciated that a vast number of variations exist. It should also be appreciated that the embodiment or embodiments are only examples, and are not intended to limit the scope, applicability, or configuration of the disclosure in any way. Rather, the foregoing detailed description will provide those skilled in the art with a convenient road map for implementing the embodiment or embodiments. It should be understood that various changes may be made in the function and arrangement of elements without departing from the scope of the disclosure as set forth in the appended claims and the legal equivalents thereof.

What is claimed is:

1. An electronic assembly comprising:
a heat sink;
a metal layer defining at least a portion of an electrical circuit; and
an electrical insulator layer disposed between the heat sink and the metal layer and directly bonded to the heat sink.

2. The electronic assembly of claim 1, wherein the electrical insulator layer has a dielectric strength of about 2 kV/mm or greater.

3. The electronic assembly of claim 1, wherein the electrical insulator layer has a dielectric strength of about 8 kV/mm or greater.

4. The electronic assembly of claim 1, wherein the electrical insulator layer has a dielectric strength of from about 8 to about 100 kV/mm.

5. The electronic assembly of claim 1, wherein the electrical insulator layer comprises a dielectric material that comprises an enamel, a polymer, or a combination thereof.

6. The electronic assembly of claim 5, wherein the electrical insulator layer comprises the enamel that comprises silicon oxide and metal oxide(s).

7. The electronic assembly of claim 5, wherein the electrical insulator layer comprises the polymer that comprises polydimethylsiloxane, epoxy, polyester, polyvinyl ester, a bismaleimide-based polymer, or combinations thereof.

8. The electronic assembly of claim 5, wherein the dielectric material comprises a filler that comprises aluminum oxide, boron nitride, magnesium oxide, silicon carbide, silicon, aluminum nitride, beryllium oxide, or combinations thereof.

9. The electronic assembly of claim 1, wherein the electrical insulator layer has a thickness of from about 0.1 to about 0.7 mm.

10. The electronic assembly of claim 1, wherein the electrical insulator layer has a thermal conductivity of about 0.3 W/m° K or greater.

11. The electronic assembly of claim 1, wherein the electrical insulator layer is directly bonded to the metal layer.

12. The electronic assembly of claim 1, further comprising a die that is electrically coupled to the electrical circuit.

13. The electronic assembly of claim 12, wherein the die is bonded to the metal layer with solder or sintered metal.

14. An electronic assembly comprising:
a heat sink;
a metal layer defining at least a portion of an electrical circuit;
an electrical insulator layer disposed between and directly bonded to the heat sink and the metal layer and having a dielectric strength of at least about 2 kV/mm; and
a die bonded to the metal layer and electrically coupled to the electrical circuit.

15. A method of fabricating an electronic assembly, the method comprising the steps of:
forming an electrical insulator layer that is disposed between a heat sink and a metal layer and that is directly bonded to the heat sink; and
defining at least a portion of an electrical circuit in the metal layer.

16. The method of claim 15, wherein the step of forming comprises:
applying an electrical insulator forming material onto the heat sink; and
drying, heating, and/or curing the electrical insulator forming material to form the electrical insulator layer.

17. The method of claim 16, wherein the electrical insulator forming material is an enamel coating, and wherein the step of forming comprises:
applying the enamel coating onto the heat sink; and
drying and/or heating the enamel coating to form the electrical insulator layer.

18. The method of claim 16, wherein the electrical insulator forming material is an uncured polymeric material, and wherein the step of forming comprises:
applying the uncured polymeric material onto the heat sink; and
heating and/or curing the uncured polymeric material to form the electrical insulator layer.

19. The method of claim 18, wherein the step of applying the uncured polymeric material comprises positioning an adhesive sheet onto the heat sink.

20. The method of claim 16, wherein applying the electrical insulator forming material comprises:
depositing the electrical insulator forming material using a liquid dispensing process, a spray process, or a laminating process.
